(19) United States
(12) Patent Application Publication
(10) Pub. No.: US 2007/0296053 A1
(43) Pub. Date: Dec. 27, 2007

(54) SEMICONDUCTOR DEVICE AND METHOD OF FORMING THE SAME

(75) Inventors: Eiji Hasunuma, Tokyo (JP); Yoshinori Tanaka, Tokyo (JP); Keizo Kawakita, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/757,505

(22) Filed: Jun. 4, 2007

(30) Foreign Application Priority Data
Jun. 8, 2006 (JP) 2006-160172

(51) Int. Cl. H01L 29/06; H01L 21/76

(52) U.S. Cl. 257/506; 438/478; 438/400; 257/618

(57) ABSTRACT

A method of forming a semiconductor device is provided. A device isolation region is formed in a semiconductor substrate, thereby defining a device region in the semiconductor substrate. The device region has a flat main surface. The flat main surface is deformed into a round surface, thereby forming a surface-rounded device region. The surface-rounded device region includes a side portion that is adjacent to a boundary with the device isolation region. The surface-rounded device region has a convex shape in vertical cross section. An epitaxial layer is selectively formed on the round surface of the surface-rounded device region. A first ion-implantation process is carried out for introducing an impurity into at least one of the epitaxial layer and the surface-rounded device region.

### BACKGROUND OF THE INVENTION

1. Field of the Invention

The present invention generally relates to a semiconductor device and a method of forming the same.

Priority is claimed on Japanese Patent Application No. 2006-160172, filed Jun. 8, 2006, the content of which is incorporated herein by reference.

2. Description of the Related Art

All patents, patent applications, patent publications, scientific articles, and the like, which will hereinafter be cited or identified in the present application, will hereby be incorporated by reference in their entirety in order to describe more fully the state of the art to which the present invention pertains.

For forming a semiconductor device, it has been known as a conventional technique that epitaxial layers are selectively grown on source and drain regions of a substrate. FIG. 1 is a fragmentary plan view illustrating a semiconductor device. FIG. 2 is a fragmentary cross sectional elevation view, taken along an A-A′ line of FIG. 1. A semiconductor substrate SU is prepared.

A device isolation region 101 is selectively provided in the semiconductor substrate SU, thereby defining a device region 103 which is surrounded by the device isolation region 101. Agate structure 102 is selectively disposed on a part of the device region 103 and a part of the device isolation region 101, thereby defining source and drain regions in the device region 103. The gate structure 102 includes a gate insulating film 111, a gate electrode 112, an insulating film 113 and sidewall spacers 114. The gate insulating film 111 is selectively disposed on the device region 103. The gate electrode 112 is disposed on the gate insulating film 111. The insulating film 113 is disposed on the gate electrode 112. The sidewall spacers 114 are disposed on sidewalls of the gate electrode 112 and the insulating film 113.

The semiconductor device is formed as follows. A silicon substrate SU is prepared. A device isolation region 101 is selectively formed in the silicon substrate SU, thereby defining a device region 103 which is surrounded by the device isolation region 101. Agate insulating film 111 is formed on the device region 103 of the silicon substrate SU. A doped polysilicon film is formed on the gate insulating film 111. A film of WSi or W is formed on the doped polysilicon film, thereby forming a gate electrode film 112 which includes the doped polysilicon film and the film of WSi or W. An insulating film 113 is formed on the film of WSi or W. The insulating film 113 acts as a gate mask. The insulating film 113 can be realized by an oxide film or a nitride film. A resist film is applied on the insulating film 113. A lithograph process is carried out to form a resist pattern on the insulating film 113.

The multi-layered structure of the gate insulating film 111, the gate electrode film 112, and the insulating film 113 is selectively removed by a selective dry etching process using the resist pattern as a mask. The resist pattern is then removed. An insulating film of silicon oxide or silicon nitride is formed on the surface of the device region 102 and on the sidewalls and the top surface of the multi-layered structure. A dry etching process is carried out to form sidewall spacers 114 on the sidewalls of the multi-layered structure, thereby forming a gate structure 102 on the device region 102. The gate structure 102 also defines source and drain regions in the device region 102.

FIGS. 3 through 5 are fragmentary cross sectional elevation views illustrating a semiconductor device in sequential steps involved in a conventional method of forming the semiconductor device. FIG. 3 is a fragmentary cross sectional elevation view, taken along an A-A′ line of FIG. 1, illustrating a semiconductor device in a step subsequent to the step shown in FIGS. 1 and 2. FIG. 4 is a fragmentary cross sectional elevation view, taken along a B-B′ line of FIG. 1, which illustrates a semiconductor device in a step subsequent to the step shown in FIG. 3. FIG. 5 is a fragmentary cross sectional elevation view, taken along a B-B′ line of FIG. 1, which illustrates a semiconductor device in a step subsequent to the step shown in FIG. 4.

As shown in FIG. 3, a selective epitaxial growth of silicon is carried out using a mixture gas of SiH₂Cl₂ and HCl, so as to form epitaxial layers 115 on the source and drain regions.

As shown in FIG. 4, an ion-implantation process is carried out so as to introduce an impurity into the epitaxial layers 115 and the source and drain regions, thereby reducing resistivity of the epitaxial layers 115 and the source and drain regions.

As shown in FIG. 5, an inter-layer insulator 116 is formed over the gate structure 102, the epitaxial layers 115 and the device isolation region 101. A resist film is applied on the inter-layer insulator 116. A lithography process is carried out to form a resist pattern on the inter-layer insulator 116. A dry etching process is carried out by using the resist pattern as a mask, so as to form a contact hole 117 in the inter-layer insulator 116. The resist pattern is removed. An ion-implantation process is carried out by using t the inter-layer insulator 116 as a mask so as to introduce an impurity into the epitaxial layers 115 through the contact hole 117, thereby reducing a contact resistance.

Japanese Unexamined Patent Application, First Publication, No. 2005-175299 discloses a conventional technique for forming a semiconductor device, while suppressing growth of facets on epitaxial silicon films that are formed on source and drain regions. Epitaxial silicon films are grown on source and drain regions. Device isolation regions are adjacent to the source and drain regions. The surface level of the device isolation region is the same as or is lower than the surface level of the source and drain regions. A stopper is formed on a part of the device isolation region, wherein the stopper is made of a different material from the device isolation region.

FIG. 6 is a fragmentary cross sectional elevation view illustrating the semiconductor device of FIG. 3, but taken along a B-B′ line of FIG. 1. Epitaxial layers 115 are selectively grown on the device region 103 that is defined by the device isolation region 101. The epitaxial layers 115 may often have facets 118 which are positioned adjacent to the boundary between the device region 103 and the device isolation region 101. In other words, the epitaxial layers 115 include a thickness-tapered portion that is adjacent to the periphery thereof. The thickness-tapered portion is thinner than the center portion of the epitaxial layers 115. The thickness-tapered portion has the facet 118.

An ion-implantation may often be carried out to introduce an impurity into the device region 103 so as to form source and drain regions in the device region 103, wherein the impurity penetrates through the epitaxial layers 115. Another ion-implantation may often be carried out to introduce an impurity into the epitaxial layers 115 so as to reduce the resistivity of the epitaxial layers 115. The depth of the implanted impurity may depend upon the thickness of the epitaxial layers 115. Namely, the thickness-tapered portion of the epitaxial layers 115 allows the implanted impurity to reach a deeper level, while the center portion that is thicker than the thickness-tapered portion allows the implanted impurity to reach a shallower level.

When ion-implantation energy is determined to allow the implanted impurity to penetrate through the center portion and to reach an intended depth, this energy may often cause the implanted impurity to penetrate through the thickness-tapered portion and to reach a deeper level than the intended depth.

FIG. 7 is a fragmentary cross sectional elevation view, taken along a B-B′ line of FIG. 1, which illustrates a semiconductor device in a step subsequent to the step shown in FIG. 4. As shown in FIG. 7, an inter-layer insulator 116′ is formed over the gate structure 102, the epitaxial layers 115 and the device isolation region 101. A resist film is applied on the inter-layer insulator 116′. A lithography process is carried out to form a resist pattern on the inter-layer insulator 116′. A dry etching process is carried out by using the resist pattern as a mask, so as to form a contact hole 117′ in the inter-layer insulator 116′. The contact hole 117′ is displaced from the intended position that is shown in FIG. 5. The resist pattern is removed. An ion-implantation process is carried out by using the inter-layer insulator 116′ as a mask so as to introduce an impurity into the epitaxial layers 115 through the contact hole 117, thereby reducing a contact resistance. As shown in FIG. 7, the facet of the epitaxial layer 115 is adjacent to the contact hole 117′. Thus, the impurity is implanted into the epitaxial layer 115. The depth of the implanted impurity depends on the thickness of the epitaxial layer 115. The thickness-tapered portion of the epitaxial layer 115 allows the implanted impurity to reach a deeper level than the intended level.

In view of the above, it will be apparent to those skilled in the art from this disclosure that there exists a need for an improved semiconductor device and/or a method of forming the semiconductor device. This invention addresses this need in the art as well as other needs, which will become apparent to those skilled in the art from this disclosure.

### SUMMARY OF THE INVENTION

Accordingly, it is a primary object of the present invention to provide a semiconductor device that is free from the above-described disadvantages.

It is another object of the present invention to provide a semiconductor device that allows a proper ion-implantation through facet portions of epitaxial layers.

It is a further object of the present invention to provide a method of forming a semiconductor device that is free from the above-described disadvantages.

It is a still further object of the present invention to provide a method of forming a semiconductor device that allows a proper ion-implantation through facet portions of epitaxial layers.

In accordance with a first aspect of the present invention, a method of forming a semiconductor device includes the following processes. A device isolation region is formed in a semiconductor substrate, thereby defining a device region in the semiconductor substrate. The device region has a flat main surface. The flat main surface is deformed into a round surface, thereby forming a surface-rounded device region. The surface-rounded device region includes a side portion that is adjacent to a boundary with the device isolation region. The surface-rounded device region has a convex shape in vertical cross section. An epitaxial layer is selectively formed on the round surface of the surface-rounded device region. A first ion-implantation process is carried out for introducing an impurity into at least one of the epitaxial layer and the surface-rounded device region.

In accordance with a second aspect of the present invention, a semiconductor device may include a semiconductor substrate, a device isolation region, a surface-rounded device region, and an epitaxial layer. The device isolation region is provided in the semiconductor substrate. The surface-rounded device region is provided in the semiconductor substrate. The surface-rounded device region has a round surface. The surface-rounded device region includes a side portion that is adjacent to a boundary with the device isolation region. The surface-rounded device region has a convex shape in vertical cross section. The epitaxial layer is provided on the round surface of the surface-rounded device region.

These and other objects, features, aspects, and advantages of the present invention will become apparent to those skilled in the art from the following detailed descriptions taken in conjunction with the accompanying drawings, illustrating the embodiments of the present invention.

### BRIEF DESCRIPTION OF THE DRAWINGS

Referring now to the attached drawings which form a part of this original disclosure:

FIG. 1 is a fragmentary plan view illustrating a semiconductor device;

FIG. 2 is a fragmentary cross sectional elevation view, taken along an A-A′ line of FIG. 1, illustrating a semiconductor device shown in FIG. 1;

FIG. 3 is a fragmentary cross sectional elevation view, taken along an A-A′ line of FIG. 1, illustrating a semiconductor device in a step subsequent to the step shown in FIGS. 1 and 2;

FIG. 4 is a fragmentary cross sectional elevation view, taken along a B-B′ line of FIG. 1, which illustrates a semiconductor device in a step subsequent to the step shown in FIG. 3;

FIG. 5 is a fragmentary cross sectional elevation view, taken along a B-B′ line of FIG. 1, which illustrates a semiconductor device in a step subsequent to the step shown in FIG. 4;

FIG. 6 is a fragmentary cross sectional elevation view illustrating the semiconductor device of FIG. 3, but taken along a B-B′ line of FIG. 1;

FIG. 7 is a fragmentary cross sectional elevation view, taken along a B-B′ line of FIG. 1, which illustrates a semiconductor device in a step subsequent to the step shown in FIG. 4;

FIG. 8 is a fragmentary cross sectional elevation view, taken along a B-B′ line of FIG. 1, which illustrates a semiconductor device in a step involved in a method of FIG. 9 is a fragmentary cross sectional elevation view, taken along a B-B′ line of FIG. 1, which illustrates a semiconductor device in another step subsequent to the step shown in FIG. 8, in accordance with the first embodiment of the present invention;

FIG. 10 is a fragmentary cross sectional elevation view, taken along an A-A′ line of FIG. 1, which illustrates a semiconductor device in still another step subsequent to the step shown in FIG. 9, in accordance with the first embodiment of the present invention;

FIG. 11 is a fragmentary cross sectional elevation view, taken along a B-B′ line of FIG. 1, which illustrates a semiconductor device in yet another step subsequent to the step shown in FIG. 10, in accordance with the first embodiment of the present invention;

FIG. 12 is a fragmentary cross sectional elevation view, taken along a B-B′ line of FIG. 1, which illustrates a semiconductor device in yet another step subsequent to the step shown in FIG. 11, in accordance with the first embodiment of the present invention; and

FIG. 13 is a fragmentary cross sectional elevation view, taken along a B-B′ line of FIG. 1, which illustrates a semiconductor device in yet another step subsequent to the step shown in FIG. 12, in accordance with the first embodiment of the present invention.

### DETAILED DESCRIPTION OF THE INVENTION

In accordance with a first aspect of the present invention, a method of forming a semiconductor device includes the following processes. A device isolation region is formed in a semiconductor substrate, thereby defining a device region in the semiconductor substrate. The device region has a flat main surface. The flat main surface is deformed into a round surface, thereby forming a surface-rounded device region. The surface-rounded device region includes a side portion that is adjacent to a boundary with the device isolation region. The surface-rounded device region has a convex shape in vertical cross section. An epitaxial layer is selectively formed on the round surface of the surface-rounded device region. A first ion-implantation process is carried out for introducing an impurity into at least one of the epitaxial layer and the surface-rounded device region.

The epitaxial layer has a generally uniform thickness. Thus, the generally uniform thickness of the epitaxial layer allows the implanted impurity to reach an intended depth from the round surface of the surface-rounded device region. In other words, the implanted impurity having penetrated through the facet reaches substantially the same level as that of the implanted impurity having penetrated through the center portion of the epitaxial layer. The generally uniform thickness of the epitaxial layer suppresses any substantive variation in depth of the implanted impurity from the round surface of the surface-rounded device region.

Deforming the flat surface into the round surface may include the following processes. The surface of the device isolation region is etched so that the etched surface of the device isolation region is lower in level than the surface of the flat surface of the device region. Annealing the semiconductor substrate is carried out to deform the flat surface into the round surface, thereby forming the surface-rounded device region.

The epitaxial layer may have a facet that has an angle of not less than 90 degrees with reference to a horizontal plane, wherein the horizontal plane is parallel to the flat main surface.

The method of forming the semiconductor device may further include the following process. A second ion-implantation process is carried out for introducing an impurity into at least one of the epitaxial layer and the surface-rounded device region in a direction vertical to the horizontal plane.

The method of forming the semiconductor device may further include the following process. A gate structure is formed on the round surface of the surface-rounded device region, thereby defining source and drain regions, before selectively forming the epitaxial layer on the source and drain regions.

The method of forming the semiconductor device may further include the following processes. An inter-layer insulator is formed over the epitaxial layer and the device isolation region. A contact hole is formed in the inter-layer insulator so that a part of the epitaxial layer is adjacent to the contact hole. An impurity is introduced into the epitaxial layer through the contact hole.

In accordance with a second aspect of the present invention, a semiconductor device may include a semiconductor substrate, a device isolation region, a surface-rounded device region, and an epitaxial layer. The device isolation region is provided in the semiconductor substrate. The surface-rounded device region is provided in the semiconductor substrate. The surface-rounded device region has a round surface. The surface-rounded device region includes a side portion that is adjacent to a boundary with the device isolation region. The surface-rounded device region has a convex shape in vertical cross section. The epitaxial layer is provided on the round surface of the surface-rounded device region.

The epitaxial layer may have a facet that has an angle of not greater than 90 degrees with reference to the surface of the device isolation region.

The epitaxial layer has a generally uniform thickness. Thus, the generally uniform thickness of the epitaxial layer allows the implanted impurity to reach an intended depth from the round surface of the surface-rounded device region. In other words, the implanted impurity having penetrated through the facet reaches substantially the same level as that of the implanted impurity having penetrated through the center portion of the epitaxial layer. The generally uniform thickness of the epitaxial layer suppresses any substantive variation in depth of the implanted impurity from the round surface of the surface-rounded device region.

Selected embodiments of the present invention will now be described with reference to the drawings. It will be apparent to those skilled in the art from this disclosure that the following descriptions of the embodiments of the present invention are provided for illustration only and not for the purpose of limiting the invention as defined by the appended claims and their equivalents.

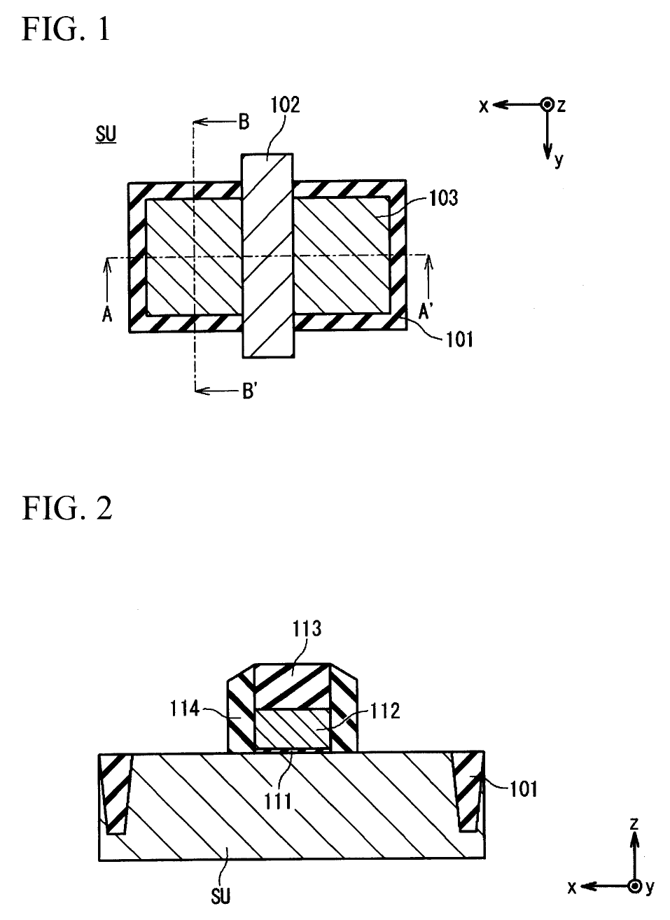

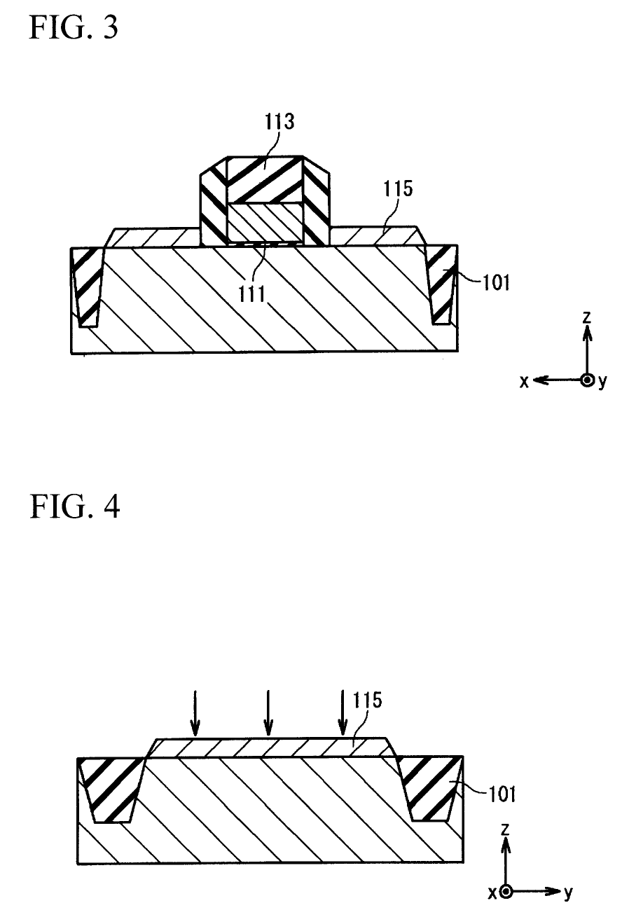

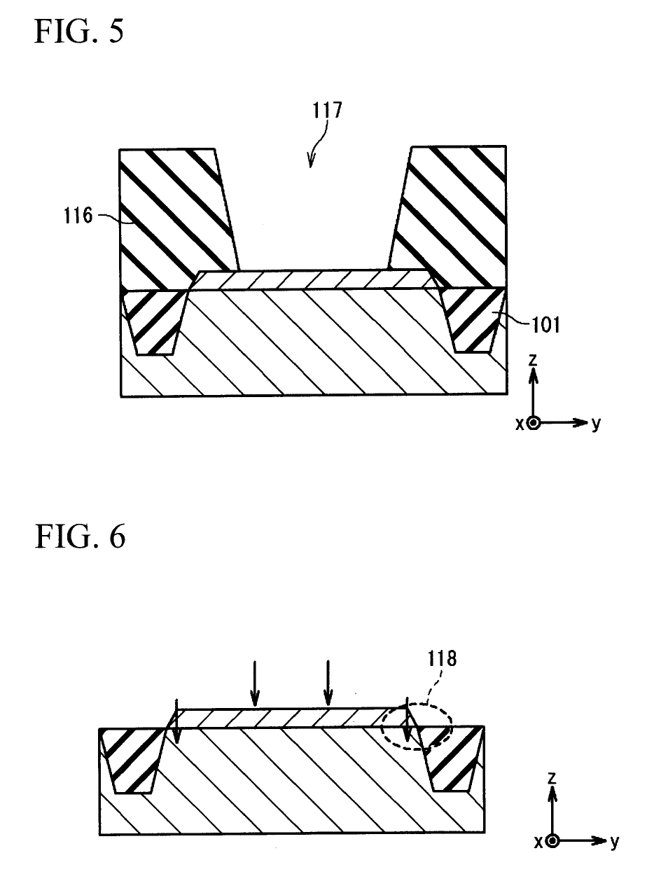

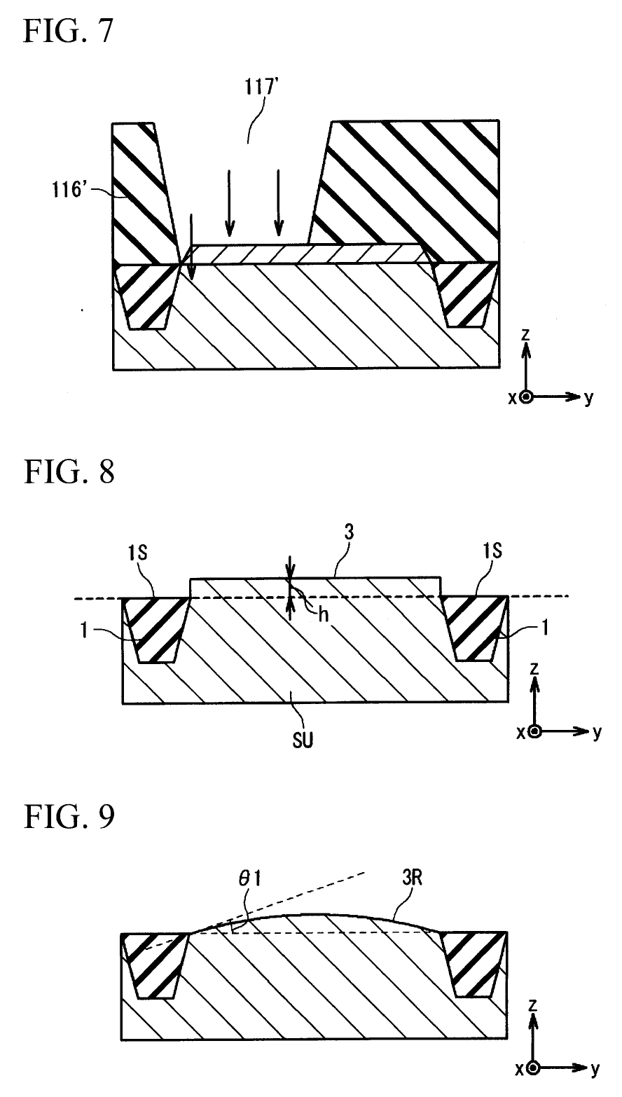

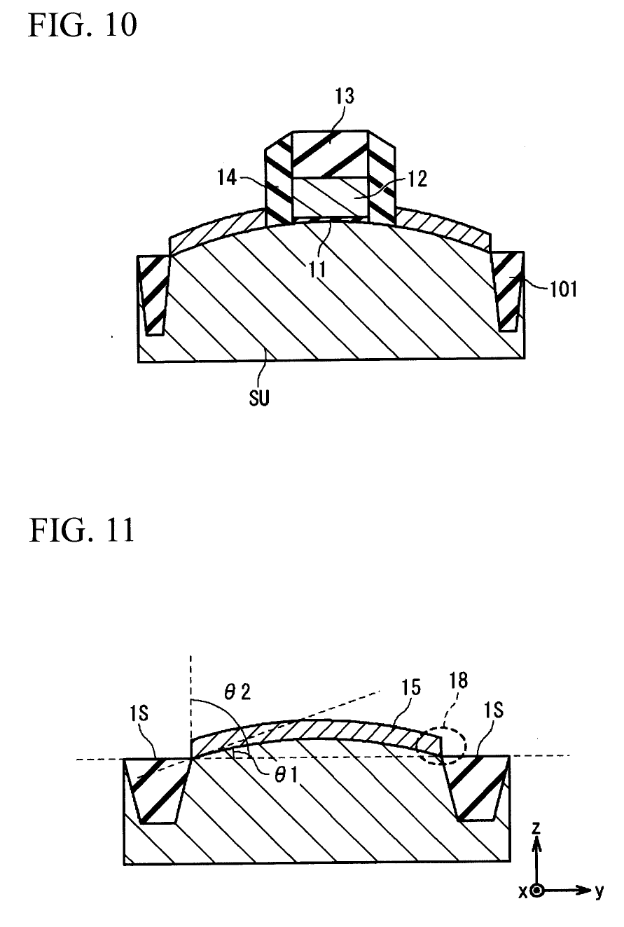

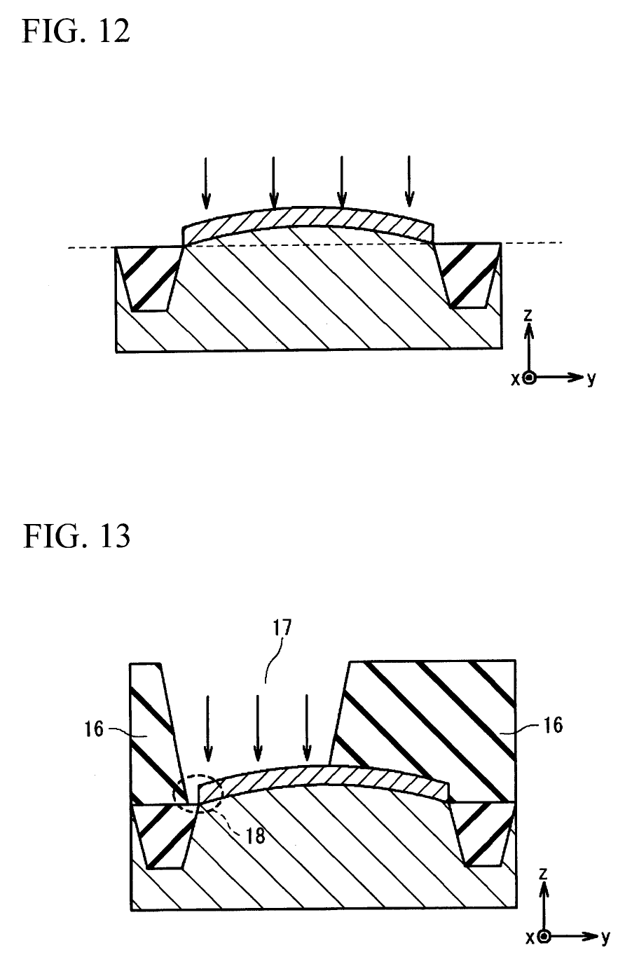

FIG. 8 is a fragmentary cross sectional elevation view, taken along a B-B′ line of FIG. 1, which illustrates a semiconductor device in a step involved in a method of forming the same in accordance with a first embodiment of the present invention. FIG. 9 is a fragmentary cross sectional elevation view, taken along a B-B′ line of FIG. 1, which illustrates a semiconductor device in another step subsequent to the step shown in FIG. 8, in accordance with the first embodiment of the present invention. FIG. 10 is a fragmentary cross sectional elevation view, taken along an A-A′ line of FIG. 1, which illustrates a semiconductor device in still another step subsequent to the step shown in FIG. 9, in accordance with the first embodiment of the present invention. FIG. 11 is a fragmentary cross sectional elevation view, taken along a B-B′ line of FIG. 1, which illustrates a semiconductor device in yet another step subsequent to the step shown in FIG. 10, in accordance with the first embodiment of the present invention. FIG. 12 is a fragmentary cross sectional elevation view, taken along a B-B′ line of FIG. 1, which illustrates a semiconductor device in yet another step subsequent to the step shown in FIG. 11, in accordance with the first embodiment of the present invention. FIG. 13 is a fragmentary cross sectional elevation view, taken along a B-B′ line of FIG. 1, which illustrates a semiconductor device in yet another step subsequent to the step shown in FIG. 12, in accordance with the first embodiment of the present invention.

As shown in FIG. 8, a silicon substrate SU is prepared. A device isolation region 1 is selectively formed in the silicon substrate SU, thereby defining a device region 3 which is surrounded by the device isolation region 1. The surface of the device region 3 has substantially the same level as the surface 1S of the device isolation region 1. The level of the surface of the substrate SU is expressed by the coordinate Z, while the surface of the substrate SU is parallel to a plane that is parallel to the coordinates X and Y and is vertical to the coordinate Z. The surface of the substrate SU is etched by an etchant such as a fluoric acid, so that the surface of the device isolation region 1 is lower in level than the surface of the device region 3. The difference in level between the surface 1S of the device isolation region 1 and the surface of the device region 3 may typically be, but is not limited to, approximately 30 nm. For example, the level of surface of the device region 3 may be indicated by zero on the coordinate Z, while the level of the surface 1S of the device isolation region 1 may be indicated by —h, where h is the difference in level between the surface of the device isolation region 1 and the surface of the device region 3, where h may typically be, but is not limited to, 30 nm.

As shown in FIG. 9, an anneal is carried out at about 900° C. in a hydrogen atmosphere so that the flat surface of the device region 3 is deformed to be a round surface, thereby forming a surface-rounded device region 3R which has a convex shape. The periphery of the surface-rounded device region 3R is continued to the surface 1S of the device isolation region 1. Heating the substrate SU deforms the flat surface of the device region 3 into the round surface. The surface of the surface-rounded device region 3R curves outwards in the middle. In other words, the surface-rounded device region 3R forms a round-hill which is continued from the surface 1S of the device isolation region 1. The level of the round surface of the surface-rounded device region 3R is smoothly and continuously increased from the level of the surface 1S of the device isolation region 1 as the position moves toward the center of the surface-rounded device region 3R from the boundary with the device isolation region 1. The surface-rounded device region 3R includes a side portion that is adjacent to the device isolation region 1. The side portion has a surface with a tangential line which is represented by a broken line. The tangential line has a first angle θ 1 with reference to the horizontal plane that is parallel to the axes X and Y The flat surface of the device region 3 is parallel to the horizontal plane. The first angle of θ 1 is greater than 0 degree and smaller than 90 degrees. Namely, the surface-rounded device region 3R includes the side portion with a slope angle which is equivalent to the first angle θ 1, wherein the side portion is adjacent to the device isolation region 1.

As shown in FIG. 10, a gate insulating film 11 is formed on the round surface of the surface-rounded device region 3R of the substrate SU. A gate electrode film 12 is formed on the gate insulating film 11. The surface of the gate electrode film 12 is planarized to form a planarized surface. An insulating film 13 is formed on the planarized surface of the gate electrode film 12, thereby forming a multi-layered structure over the round surface of the surface-rounded device region 3R of the substrate SU. The multi-layered structure includes the gate insulating film 11, the gate electrode film 12 and the insulating film 13. A resist film is applied on the insulating film 13. The resist film is patterned to form a resist pattern. A dry etching process is carried out by using the resist pattern as a mask to selectively etch the multi-layered structure, thereby forming a gate electrode structure. Sidewall spacers 14 are formed on sidewalls of the gate electrode structure. A selective epitaxial growth of silicon is carried out using a mixture gas of SiH₂Cl₂ and HCl, so as to form epitaxial layers 15 on the source and drain regions. The round surface of the surface-rounded device region 3R allows the epitaxial layers 15 to have a generally uniform thickness. Namely, the cross sectioned shape of the epitaxial layers 15 is similar to the round surface of the surface-rounded device region 3R.

As shown in FIG. 11, the epitaxial layers 15 each have a facet 18 which is positioned adjacent to the boundary between the surface-rounded device region 3R and the device isolation region 1. The facet 18 of the epitaxial layer 15 has a second angle θ 2 with reference to the tangential line of the side portion of the surface-rounded device region 3R. The sum of the first and second angles θ 1 and θ 2 is defined by an included angle between the facet 18 and the horizontal plane. The horizontal plane is parallel to the axes X and Y The main surface of the substrate SU is parallel to the horizontal plane. The facet 18 of the epitaxial layer 15 has a third angle with reference to the horizontal plane. The third angle is equal to the sum of the first and second angles θ 1 and θ 2. It is preferable that the first and second angles θ 1 and θ 2 satisfy the following conditions.

θ 1+θ 2≧90° degrees

A plurality of semiconductor devices having similar shapes is formed on the substrate SU. The semiconductor devices are disposed on the main surface of the substrate SU. It is preferable that the third angle between the facet 18 and the horizontal plane is not smaller than 90 degrees. In other words, an angle between the facet 18 of the epitaxial layer 15 and the surface 1S of the device isolation region 1 is less than 90 degrees.

As shown in FIG. 12, an ion-implantation process is carried out to introduce an impurity into the epitaxial layers 15 and the surface-rounded device region 3R. The impurity is implanted in a direction that is generally parallel to the axis Z. As described above, the epitaxial layers 15 have the generally uniform thickness. Thus, the generally uniform thickness of the epitaxial layers 15 allows the implanted impurity to reach an intended depth from the round surface of the surface-rounded device region 3R. In other words, the implanted impurity having penetrated through the facet 18 reaches substantially the same level as that of the implanted impurity having penetrated through the center portion of the epitaxial layers 15. The generally uniform thickness of the epitaxial layers 15 suppresses any substantive variation in depth of the implanted impurity from the round surface of the surface-rounded device region 3R.

As shown in FIG. 13, an inter-layer insulator 16 is formed over the gate electrode structure with the sidewall spacers 14, the epitaxial layers 15, and the surface S1 of the device isolation region 1. A resist film is applied on the inter-layer insulator 16. The resist film is patterned by a lithography process to form a resist pattern on the inter-layer insulator 16. A dry etching process is carried out using the resist pattern as a mask so as to form a contact hole 17 in the inter-layer insulator 16. It is intended that the center of the contact hole 17 is aligned to the center of the surface-rounded device region 3R or the center of the gate electrode. It is, however, possible that the center of the contact hole 17 is undesirably displaced from the center of the surface-rounded device region 3R or the center of the gate electrode. In a case, the displacement may be large so that the facet 18 of the epitaxial layer 15 and a part of the surface S1 of the device isolation region 1 are adjacent to the contact hole 17 as shown in FIG. 13. The resist pattern is removed.

A further ion-implantation is carried out by using the inter-layer insulator 16 to introduce an impurity into the surface-rounded device region 3R. The impurity is implanted in the direction that is generally parallel to the axis Z. As described above, the epitaxial layers 15 have the generally uniform thickness. Thus, the generally uniform thickness of the epitaxial layers 15 allows the implanted impurity to reach an intended depth from the round surface of the surface-rounded device region 3R. In other words, the implanted impurity having penetrated through the facet 18 reaches substantially the same level as that of the implanted impurity having penetrated through the center portion of the epitaxial layers 15. The generally uniform thickness of the epitaxial layers 15 suppresses any substantive variation in depth of the implanted impurity from the round surface of the surface-rounded device region 3R.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A method of forming a semiconductor device, the method comprising:
forming a device isolation region in a semiconductor substrate, thereby defining a device region in the semiconductor substrate, the device region having a flat main surface;
deforming the flat main surface into a round surface, thereby forming a surface-rounded device region, the surface-rounded device region including a side portion that is adjacent to a boundary with the device isolation region, the surface-rounded device region having a convex shape in vertical cross section;
selectively forming an epitaxial layer on the round surface of the surface-rounded device region; and
carrying out a first ion-implantation process for introducing an impurity into at least one of the epitaxial layer and the surface-rounded device region.

2. The method according to claim 1, wherein deforming the flat surface into the round surface comprises:
etching the surface of the device isolation region so that the etched surface of the device isolation region is lower in level than the surface of the flat surface of the device region; and
annealing the semiconductor substrate.

3. The method according to claim 1, wherein the epitaxial layer has a facet that has an angle of not less than 90 degrees with reference to a horizontal plane, the horizontal plane is parallel to the flat main surface.

4. The method according to claim 3, further comprising:
carrying out a second ion-implantation process for introducing an impurity into at least one of the epitaxial layer and the surface-rounded device region in a direction vertical to the horizontal plane.

5. The method according to claim 1, further comprising:
forming a gate structure on the round surface of the surface-rounded device region, thereby defining source and drain regions, before selectively forming the epitaxial layer on the source and drain regions.

6. The method according to claim 1, further comprising:
forming an inter-layer insulator over the epitaxial layer and the device isolation region;
forming a contact hole in the inter-layer insulator so that a part of the epitaxial layer is adjacent to the contact hole; and
introducing an impurity into the epitaxial layer through the contact hole.

7. A semiconductor device comprising:
a semiconductor substrate;
a device isolation region provided in the semiconductor substrate;
a surface-rounded device region provided in the semiconductor substrate, the surface-rounded device region having a round surface, the surface-rounded device region including a side portion that is adjacent to a boundary with the device isolation region, the surface-rounded device region having a convex shape in vertical cross section; and
an epitaxial layer provided on the round surface of the surface-rounded device region.

8. The semiconductor device according to claim 7, wherein the epitaxial layer has a facet that has an angle of not greater than 90 degrees with reference to the surface of the device isolation region.
